(19) United States
(12) Patent Application Publication
(10) Pub. No.: US 2008/0210296 A1
(43) Pub. Date: Sep. 4, 2008

(54) Dye-Sensitized Photovoltaic Device, Method for Making the Same, Electronic Device, Method for Making the Same, and Electronic Apparatus

(76) Inventors: Masahiro Morooka, Kanagawa (JP); Reiko Ogura, Kanagawa (JP); Yusuke Suzuki, Kanagawa (JP)

Correspondence Address: WOLF GREENFIELD & SACKS, P.C., 600 ATLANTIC AVENUE, BOSTON, MA, 02210-2206, US

(21) Appl. No.: 11/885,361

(22) PCT Filed: Feb. 7, 2006
(86) PCT No.: PCT/JP06/02056

§ 371 Date: Aug. 30, 2007

(30) Foreign Application Priority Data
Mar. 11, 2005 (JP) 2005-068671

(51) Int. Cl. H01L 31/0232; H01L 31/04; H01L 31/18

(52) U.S. Cl. 136/252; 438/72; 257/E31.127

(57) ABSTRACT

In a dye-sensitized photovoltaic device including a semiconductor fine particle layer 2 on which a sensitizing dye is adsorbed, a counter electrode 3, and an electrolyte layer 4 between the electrodes, a molecule having a plurality of acid functional groups for adsorption onto the semiconductor electrode is used as a molecule of the sensitizing dye, and part of the acid functional groups is neutralized with an alkaline compound which is a hydroxide of at least one metal or compound selected from the group consisting of Li, Na, K, tetramethylammonium, tetraethyl ammonium, tetrapropyl ammonium, tetrabutyl ammonium, an imidazolium compound, and a pyridinium compound. In this manner, a dye-sensitized photovoltaic device that can achieve high photoelectric conversion efficiency even in the cases where a dye containing readily aggregating acid functional groups, such as carboxylic acid, as the adsorbing groups is used. A method for making the device is also provided.

### TECHNICAL FIELD

The present invention relates to a dye-sensitized photovoltaic device, a method for making the device, an electronic device, a method for making the device, and an electronic apparatus. For example, the invention is suited for applications to dye-sensitized solar cells including semiconductor electrodes composed of dye-carrying semiconductor fine particles.

### BACKGROUND ART

It is generally accepted that use of fossil fuel such as coal and petroleum as the energy sources causes global warming by carbon dioxide generated thereby. If nuclear energy is used, then there is a risk of radiation contamination. Since environmental issues are much discussed today, dependency on these energies raises many problems.

In contrast, solar cells, which are photovoltaic devices that convert sunlight to electrical energy, use sunlight as the energy source. Thus, solar cells have little effects on global environment and are expected to become more wide spread.

There are various materials available for solar cells. Solar cells that use silicon are widely commercially available, and these solar cells can be roughly divided into crystalline silicon solar cells that use single-crystal or polycrystal silicon and amorphous silicon solar cells. In the past, single-crystal or polycrystal silicon, i.e., crystalline silicon, has been widely used in the solar cells.

However, although crystalline silicon solar cells have a photoelectric conversion efficiency (indicator of performance of converting optical (sun) energy to electrical energy) higher than that of amorphous silicon solar cells, they require a lot of energy and time for growing crystals, resulting in low productivity. Thus, they are not favorable from the standpoint of cost.

Amorphous silicon solar cells have a light-absorbance higher than that of crystalline silicon solar cells, allow a wide selection range of substrates, and easily permit an increase in size. However, the photoelectric conversion efficiency is lower than that of the crystalline silicon solar cells. Moreover, although amorphous silicon solar cells boast higher productivity, the production thereof requires vacuum process and the cost for facility is still high.

In aiming to further reduce the cost of solar cells, solar cells that use organic materials rather than silicon materials have been vigorously investigated. However, the photoelectric conversion efficiency of such solar cells is as low as about 1% or less and the durability of such solar cells is also unsatisfactory.

Under such circumstances, Document 1 (Nature, 353, pp. 737-740, 1991) reported a low-cost solar cell that uses dye-sensitized semiconductor fine particles. This solar cell is a wet-type solar cell with a photoelectrode made of a titanium oxide porous thin film that has been spectrally sensitized with a ruthenium complex as a sensitizing dye. In other words, this solar cell is an electrochemical photocell. The advantages of the dye-sensitized solar cell include: low-cost titanium oxide can be used; the light-absorption of the sensitizing dye covers a wide visible light wavelength range up to 800 nm; and the quantum efficiency of the photoelectric conversion is high and high energy conversion efficiency can be achieved. Furthermore, since no vacuum process is required for the production, a large-scale facility is not necessary.

Examples of the widely known sensitizing dye for the dye-sensitized solar cells include dye molecules having carboxylic acids as adsorbing groups (for example, refer to Document 2 (Inorg. Chem. 1999, 38, 6298-6305) and Document 3 (Japanese Unexamined Patent Application Publication No. 2004-176072)). Carboxylic acids readily adsorb onto surfaces of oxides and can render a semiconductor electrode to carry the sensitizing dye by simply dipping the semiconductor electrode in a dye solution without any special treatment.

A method for making a TiO₂ paste in which titanium oxide (TiO₂) fine particles are dispersed is known (e.g., refer to Document 4, Hironori ARAKAWA, Latest Technology of Dye-Sensitized Solar Cells, CMC Publishing Co., Ltd., pp. 45-47 (2001)).

### DISCLOSURE OF INVENTION

However, such a dye-sensitized solar cell that uses a dye molecule containing a carboxylic acid adsorbing group as the sensitizing dye has a drawback in that the photoelectric conversion efficiency decreases inevitably. This is because carboxylic acids readily form aggregates and, in the case where the sensitizing dye forms aggregates on the semiconductor surface, electron injection to the semiconductor is inhibited by electron traps between dye molecules.

An object of the present invention is to provide a dye-sensitized photovoltaic device such as a dye-sensitized solar cell capable of achieving high photoelectric conversion efficiency even when a dye containing, as an adsorbing group, an acid functional group such as carboxylic acid that readily forms aggregates is used as the sensitizing dye. It also provides a method for making such a device, an electronic device containing such a dye-sensitized photovoltaic device unit, a method for making such an electronic device, and an electronic apparatus that uses such a dye-sensitized photovoltaic device.

The present inventors have conducted extensive research to overcome the problems described above, which can be summarized as follows.

As an example, the case in which a molecule of a sensitizing dye has a plurality of carboxylic acids (—COOH) as the acid functional groups is studied. As shown in FIG. 6A, aggregation occurs as the carboxyl groups in the sensitizing dye molecules form hydrogen bonds (indicated by dotted lines) with each other.

The present inventors have investigated techniques for preventing such aggregation and conceived neutralization of acid functional groups in the sensitizing dye molecules with an alkaline compound, e.g., NaOH. As a result of the neutralization, COO⁻ derived from COOH in the sensitizing dye molecule bonds with Na⁺ to give COO⁻Na⁺; however, since they are dissociated in the solution, COO⁻ remains. Since neutralized and dissociated COO⁻ is an anion, the sensitizing dye molecules are prevented from aggregating through repulsive force (charge repulsion) working between negative charges of the anions (FIG. 6B). Thus, for example, in the case where a semiconductor electrode is immersed in a solution of this dye to allow the semiconductor electrode to carry the sensitizing dye, the sensitizing dye molecules are suppressed from aggregating on the semiconductor surface, and the number of electron traps between the dyes can be significantly reduced.

This basically holds true for cases involving other acid functional groups such as a phosphoric acid group and other alkaline compounds such as KOH.

This invention is made on the basis of such findings.

In order to overcome the problems described above, a first invention provides a dye-sensitized photovoltaic device including a semiconductor electrode having a sensitizing dye adsorbed thereon, a counter electrode, and an electrolyte layer interposed between the electrodes, where a molecule of the sensitizing dye has a plurality of acid functional groups for adsorption onto the semiconductor electrode, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

A second invention provides a method for making a dye-sensitized photovoltaic device including a semiconductor electrode having a sensitizing dye adsorbed thereon, a counter electrode, and an electrolyte layer interposed between the electrodes,

where a molecule having a plurality of acid functional groups for adsorption onto the semiconductor electrode is used as a molecule of the sensitizing dye, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

Among these metals or compounds, Na, K, tetramethylammonium, tetraethylammonium, tetrapropylammonium, and a 1-ethyl-3-methylimidazolium compound are preferable. Among these, inorganic alkalis (alkaline metals), i.e., Na and K, are particularly preferable. These inorganic alkalis not only have an effect of improving the conductivity of the semiconductor electrode composed of titanium oxide or the like but also can increase the adsorption density of the sensitizing dye onto the semiconductor electrode since their ion radii are small.

The method for neutralizing the sensitizing dye molecules is not particularly limited. For example, neutralization may be conducted by mixing prescribed moles of sensitizing dye and alkaline compound or by pH titration. Partial neutralization of the sensitizing dye may be conducted before preparation of the dye solution or by adding a prescribed amount of alkali to the dye solution. Since water is produced by neutralization in the case where the sensitizing dye molecules are neutralized in the dye solution, an additional operation to remove the water may be conducted.

A sensitizing dye molecule has a plurality of acid functional groups, some of which are to be neutralized. However, when the amount of neutralized part of the sensitizing dye molecules is excessively small, suppression of aggregation between the sensitizing dye molecules is insufficient, and if this amount is excessively large, adsorbing force between the sensitizing dye molecules is decreased, and sufficient photoelectrical conversion cannot be conducted. Thus, there exists an adequate amount of neutralization. The amount of neutralization is preferably 0.25 to 0.75 and more preferably 0.35 to 0.65 with respect to the number of acid functional groups in a sensitizing dye molecule. This amount of neutralization may be reworded as the ratio of the functional groups neutralized with respect to the total number of acid functional groups in the whole sensitizing dye molecule.

The sensitizing dye is not particularly limited as long as the dye has a sensitizing function. However, the sensitizing dye must contain an acid functional group to adsorb onto the semiconductor electrode. Sensitizing dyes that contain a carboxyl group or a phosphoric acid group are preferable, and sensitizing dyes that contain a carboxyl group are particularly preferred. Examples of the sensitizing dye include xanthene dyes such as rhodamine B, rose bengal, eosin, and erythrosine; cyanine dyes such as merocyanine, quinocyanine, and cryptocyanine; basic pigments such as phenosafranine, capri blue, thiocin, and methylene blue; and porphyrin compounds such as chlorophyll, zinc porphyrin, and magnesium porphyrin. Other examples are azo dyes, phthalocyanine compounds, coumarin compounds, bipyridine complex compounds, anthraquinone pigments, and polycyclic quinone pigments. Among these, a sensitizing dye which is a complex containing at least one metal selected from the group consisting of Ru, Os, Ir, Pt, Co, Fe, and Cu and a ligand containing a pyridine ring or a imidazolium ring is particularly preferable for its high quantum yield. In particular, a sensitizing dye molecule having a basic skeleton of cis-bis(isothiocyanato)-N,N-bis(2,2′-dipyridyl-4,4′-dicarboxylic acid)-ruthenium(II) or tris(isothiocyanato)-ruthenium(II)-2,2′:6′,2″-terpyridine-4,4′,4″-tricarboxylic acid is particularly preferred since it has a wide absorption wavelength range. However, the sensitizing dyes are not limited to these and these sensitizing dyes may be used as a mixture of two or more of these.

The method for allowing the sensitizing dye to adhere on the semiconductor electrode is not limited. For example, the above-described sensitizing dye may be dissolved in a solvent such as an alcohol, a nitrile, nitromethane, halogenated hydrocarbon, an ether, dimethyl sulfoxide, an amide, N-methylpyrrolidone, 1,3-dimethylimidazolidinone, 3-methyloxazolidinone, an ester, a carbonate, a ketone, hydrocarbon, or water, and the semiconductor electrode may be immersed in the resulting dye solution or the resulting dye solution may be applied on the semiconductor electrode. Furthermore, deoxycholic acid or the like may be added to reduce aggregation of the sensitizing dye molecules. An ultraviolet absorber may also be used.

After adsorption of the sensitizing dye, the surface of the semiconductor electrode may be treated with an amine to accelerate removal of the excessive sensitizing dye adsorbed on the electrode. Examples of the amine include pyridine, 4-tert-butylpyridine, and polyvinyl pyridine. When the amines are liquid, they may be used as they are or they may be mixed in organic solvents.

In a dye-sensitized photovoltaic device such as a dye-sensitized solar cell, an additive containing a substance that bonds to the semiconductor electrode is usually added to prevent reverse electron transfer in the electrolyte. As the additive, tert-butylpyridine, 1-methoxybenzimidazole, and a phosphonic acid having a long-chain alkyl group (ca. C=13) are used. The features of these additives are that they can be homogeneously mixed in an electrolyte and that they have functional groups that can bond to the semiconductor electrode. However, the experiments conducted by the present inventors have shown that, in an existing dye-sensitized solar cell, the sensitizing dye that has been adsorbed on the surface of the semiconductor electrode in advance becomes eluted after enclosing the electrolyte, thereby resulting in a rapid decrease in photoelectrical conversion efficiency. Thus, it is necessary to present elusion of the sensitizing dye adsorbed on the semiconductor electrode in advance while preventing reverse electron transfer reaction in order to increase the photoelectrical conversion efficiency. To achieve this, rather than adding additives to the electrolyte, it is effective to allow the sensitizing dye and the additive to adsorb onto the semiconductor electrode in advance such that the additive is adsorbed onto the gaps between the sensitizing dyes and that no additives are contained in the electrolyte. For example, a possible process is to immerse a semiconductor electrode onto which the sensitizing dye is adsorbed in a solution containing additive so as to allow the additive to adsorb on the surface of the semiconductor electrode in the gaps between the sensitizing dyes and then to enclose an additive-free electrolyte between the semiconductor electrode onto which the sensitizing dye and the additive are adsorbed and the counter electrode. In this manner, the elution of the sensitizing dye by the electrolyte can be prevented while preventing the reverse electron transfer reaction by the additive adsorbed on the semiconductor electrode, and the deterioration in photoelectrical conversion efficiency over time can be effectively prevented. As additives, molecules containing functional groups capable of bonding to the semiconductor electrode (such as an imidazolyl group, a carboxyl group, and a phosphonic group), not causing desorption as a result of the bonding, and being capable of suppressing exposure of the surface of the semiconductor electrode by adsorption are used. Examples thereof include tert-butylpyridine, 1-methoxybenzimidazole, and phosphonic acids having long-chain alkyl groups (ca. C=13) such as decane phosphoric acid.

The semiconductor electrode is typically disposed on a transparent conductive substrate. The transparent conductive substrate may be one produced by forming a transparent conductive film on a conductive or non-conductive transparent support substrate or may be a transparent entirety of which is conductive. The material for the transparent support substrate is not particularly limited and various transparent substrate materials may be used. The transparent support substrate preferably has excellent blocking property against water or gas entering from outside the photovoltaic device, solvent resistance, and weathering resistance. Specific examples thereof include transparent inorganic substrates such as quartz and glass, and transparent plastic substrates such as polyethylene terephthalate, polyethylene naphthalate, polycarbonate, polystyrene, polyethylene, polypropylene, polyphenylene sulfide, poly(vinylidene fluoride), tetraacetylcellulose, brominated phenoxy, aramids, polyimides, polystyrenes, polyarylates, polysulfones, and polyolefin. It is particularly preferable to use a substrate having a high transmittance in the visible light region but the substrate is not limited to this. It is preferable to use a transparent plastic substrate as the transparent support substrate from the standpoint of processability and light-weightness. The thickness of the transparent support substrate is not particularly limited and may be freely selected according to the light transmittance and blocking property of the photovoltaic device between the interior and the exterior.

The surface resistance (sheet resistance) of the transparent conductive substrate is preferably as low as possible. In particular, the surface resistance of the transparent conductive substrate is preferably 500 Ω/□ or less and preferably 100 Ω/□ or less. In forming a transparent conductive film on a transparent support substrate, a known material may be used. Nonlimiting examples of the material include indium-tin complex oxide (ITO), fluorine-doped SnO₂ (FTO), SnO₂, ZnO, and indium-zinc complex oxide (IZO). These may be used in combination of two or more. In order to reduce the surface resistance of the transparent conductive substrate and increase the power collecting efficiency, wiring composed of a conductive material such as a metal having a high conductivity may be additionally formed on the transparent conductive substrate. There is no limit on the conductive material used for wiring, but the material preferably has high corrosion resistance and oxidation resistance, and the leakage current of the conductive material itself is preferably low. However, a conductive material with low corrosion resistance can be used if it is provided with a protective layer composed of a metal oxide or the like. In order to protect the wiring from corrosion or the like, it is preferable to provide the wiring between the transparent conductive substrate and the protective layer.

A dye-sensitized photovoltaic device, such as a dye-sensitized solar cell, usually has a structure in which an electrolyte, which is a liquid hole transfer layer, is permeated into a semiconductor electrode composed of an n-type semiconductor. Thus, there are portions where the electrolyte comes into direct contact with the transparent conductive substrate, and there arises a problem of leakage current by reverse electron transfer reaction from the transparent conductive substrate to the electrolyte. Since this leakage current decreases the fill factor and open circuit voltage of the dye-sensitized photovoltaic device, the leakage current is significantly problematic in increasing the photoelectric conversion efficiency. It is thus important to significantly reduce the leakage current from the transparent conductive substrate to the electrolyte by reverse electron transfer reaction. In order to do so, it is effective to use a transparent conductive substrate including, from the light-receiving-side, a transparent substrate, a transparent conductive layer, and a protective layer composed of a metal oxide sequentially stacked. In this manner, the transparent conductive layer is covered with the protective layer composed of the metal oxide and become separated from the electrolyte. Since the transparent conductive layer does not come into direct contact with the electrolyte, the leakage current can be significantly reduced. Furthermore, such a dye-sensitized photovoltaic device with the transparent conductive substrate has high fill factor and high open circuit voltage and can realize a dye-sensitized photovoltaic device with high photoelectric conversion efficiency. The protective layer is preferably transparent. For example, a metal oxide constituting the protective layer is at least one metal oxide selected from the group consisting of Nb₂O₅, Ta₂O₅, TiO₂, Al₂O₃, ZrO₂, TiSrO₃, and SiO₂. The thickness of the protective layer is not particularly limited. At an excessively small thickness, the transparent conductive layer is not sufficiently separated from the electrolyte. At an excessively large thickness, a decrease in transmittance and loss in electron injection to the transparent conductive layer will result. Thus, there exists a preferable thickness. This thickness is usually 0.1 to 500 nm and preferably 1 to 100 nm. The transparent conductive layer also contains at least one metal oxide selected from the group consisting of In—Sn complex oxide (ITO), In—Zn complex oxide (IZO), SnO₂ (including those dope with fluorine (F), antimony (Sb), or the like), and ZnO.

The semiconductor electrode is usually composed of semiconductor fine particles. As the material of the semiconductor fine particles, elemental semiconductors such as silicon, various compound semiconductors, and compounds having a perovskite structure can be used. These semiconductors are preferably n-type semiconductors in which conduction-band electrons become carriers by photoexcitation to give anode current. Examples of the semiconductors include TiO₂, ZnO, WO₃, Nb₂O₅, TiSrO₃, and SnO₂. Among these, anatase TiO₂ is particularly preferable. The type of semiconductor is not limited to these, and these semiconductors may be used in combination of two or more. The semiconductor fine particles may be granular, tubular, rod-like, or any other suitable form to meet the need.

Although there is no particular limit on the particle size of the semiconductor fine particles, the average particle size of the primary particles is preferably 1 t0 200 nm, and more preferably 5 to 100 nm. It is also possible to scatter the incident light by semiconductor fine particles with a large average particle size prepared by mixing the semiconductor fine particles having an average particle size in the range described above with other semiconductor fine particles having an average particle size larger than this so as to increase the quantum yield. In such a case, the average particle size of the semiconductor fine particles separately added is preferably 20 to 500 nm.

Although the process of making the semiconductor electrode composed of the semiconductor fine particles is not particularly limited, a wet film-forming process is preferred when physical properties, convenience, and production costs are considered. Preferred is a method of preparing a paste in which powder or sol of the semiconductor fine particles is homogeneously dispersed in a solvent such as water and applying the paste on a transparent conductive substrate. There is no limit imposed on the process of application, and any known suitable process may be employed. For example, application may be carried out by a dip method, a spray method, a wire bar method, a spin-coating method, a roller-coating method, a blade-coating method, or a gravure coating method. Examples of the wet printing method include anastatic printing, off-set printing, gravure printing, intaglio printing, rubber plate printing, and screen printing. When crystalline titanium oxide is used as the material of the semiconductor fine particles, the crystal type thereof is preferably anatase from the standpoint of photocatalytic activity. Anatase titanium oxide may be any commercially available powder, sol, or slurry, or may be prepared by a known method, such as hydrolysis of titanium oxide alkoxide to prepare particles with a predetermined size. When a commercially available powder is used, it is preferable to eliminate secondary aggregation of the particles. It is preferable to disintegrate particles using a mortar or a ball mill during the preparation of the coating solution. In such a case, in order to prevent re-aggregation of the particles formed by eliminating the secondary aggregation, acetyl acetone, hydrochloric acid, nitric acid, a surfactant, a chelating agent, or the like may be added. Various thickeners such as polymers, e.g., polyethylene oxide and polyvinyl alcohol, and cellulose thickeners may also be added to increase the viscosity.

The semiconductor fine particle layer preferably has a large surface area so that large amounts of sensitizing dye can be adsorbed. Thus, the surface area of the semiconductor fine particle layer as applied on the support is preferably 10 times and more preferably 100 times the project area or more. Although there is no upper limit, the upper limit is usually about 1000 times. In general, the semiconductor fine particle layer can carry a larger amount of dye per unit project area as the thickness is increased and thus shows a higher light-capturing rate. However, since the diffusion length of the injected electrons also increases, the loss caused by recombination of charges is also increased. Thus, there exists a preferable thickness for the semiconductor fine particle layer. The thickness is usually 0.1 to 100 μm, preferably 1 to 50 μm, and more preferably 3 to 30 μm. The semiconductor fine particle layer is preferably fired to allow the particles to electronically contact with each other after application on the support and to increase the strength and the adhesion to the substrate. Although there is no special limit is imposed on the range of firing temperature, the resistance of the substrate becomes high at an excessively high temperature which may result in melting. Thus, the temperature is usually 40° C. to 700° C. and preferably 40° C. to 650° C. The length of time of firing is also not limited but is usually about 10 minutes to 10 hours. After firing, dip treatment in an aqueous titanium tetrachloride solution or a titanium oxide ultrafine particle sol may be conducted to increase the surface area of the semiconductor fine particle layer and to increase the necking between the semiconductor fine particles. In the case where a plastic substrate is used as the support of the transparent conductive substrate, a paste containing a binder may be applied on the substrate to conduct press-bonding onto the substrate by thermal pressing.

The counter electrode may be composed of any conductive substance. An insulating substance can also be used as long as a conductive layer is provided at the side facing the semiconductor substrate. The material of the counter electrode is preferably electrochemically stable, and preferably platinum, gold, carbon, or a conductive polymer is used. In order to increase the catalytic effect of involving oxidation-reduction, the side facing the semiconductor electrode preferably has a microstructure with an increased surface area. For example, if platinum is used, a platinum black state is preferred, and if carbon is used, a porous state is preferred. The platinum black state can be created by anodization of platinum, treatment with chloroplatinic acid, or the like, and carbon in the porous state can be created by sintering the carbon fine particles, firing an organic polymer, or the like. Moreover, a wiring of a metal, such as platinum, having a high oxidation-reduction catalytic effect may be formed on a transparent conductive substrate or the surface of the transparent conductive substrate may be treated with chloroplatinic acid so that the substrate can be used as a transparent counter electrode.

Examples of the usable electrolyte include a combination of iodine (I₂) and a metal iodide or an organic iodide, a combination of bromine (Br₂) and a metal bromide or an organic bromide, metal complexes such as ferrocyanate/ferricyanate and ferrocene/ferricinium ion, sulfur compounds such as sodium polysulfide and alkyl thiol/alkyl disulfide, viologen dyes, and hydroquinone/quinone. As the cation of the metal compounds above, Li, Na, K, Mg, Ca, and Cs are preferred, and as the cation of the organic compounds, quaternary ammoniums such as tetraalkylammoniums, pyridiniums, and imidazoliums are preferred but the cations are not limited to these. These cations may be used in combination of two or more. Among these, an electrolyte which is a combination of I₂ and LiI, NaI, or a quaternary ammonium compound such as imidazolium iodide is preferred. The concentration of the electrolyte salt is preferably 0.05 to 10 M and more preferably 0.2 to 3 M with respect to the solvent. The concentration of I₂ or Br₂ is preferably 0.0005 to 1 M and more preferably 0.001 to 0.5 M. Various additives such as 4-tert-butylpyridine and benzimidazoliums may be added to improve the open circuit voltage and the short circuit current.

Examples of the solvent constituting the electrolyte composition described above include water, alcohols, ethers, esters, carbonic esters, lactones, carboxylic esters, phosphoric triesters, heterocyclic compounds, nitrites, ketones, amides, nitromethane, halogenated hydrocarbons, dimethylsulfoxide, sulfolane, N-methylpyrrolidone, 1,3-dimethylimidazolidinone, 3-methyloxazolidinone, and hydrocarbon, but the solvent is not limited to these. These may be used in combination of two or more. It is also possible to use a room-temperature ionic liquid based on tetraalkyl, pyridinium, or imidazolium quaternary ammonium salts.

In order to reduce liquid leakage and evaporation of the electrolyte from the photovoltaic device, a gel electrolyte prepared by dissolving a gelation agent, a polymer, a cross-linking monomer, or the like in the above-described electrolyte composition can be used. The higher the ratio of the gel matrix to the electrolyte composition, the higher then ion conductivity and the lower the mechanical strength. In contrast, when the ratio of the electrolyte composition is excessively small, the ion conductivity is decreased although the mechanical strength is increased. Thus, the ratio of the electrolyte composition is preferably 50 to 99 wt % and more preferably 80 to 97 wt % of the gel electrolyte. It is also possible to realize an all-solid photovoltaic device by dissolving the electrolyte and the plasticizer in a polymer and removing the plasticizer by evaporation.

The method for making the photovoltaic device is not particularly limited. For example, in the cases where the electrolyte composition is liquid or liquid (before introduction) that can be gelated inside the photovoltaic device, a semiconductor electrode carrying the dye is disposed to face the counter electrode and the portions of the substrate free of the semiconductor electrode is sealed while preventing these electrodes to contact each other. The distance between the semiconductor electrode and the counter electrode is not particularly limited but is usually 1 to 100 μm and more preferably 1 to 50 μm. If the distance between the electrodes is excessively large, the light current decreases by the decrease in conductivity. Although the method for sealing is not particularly limited, a material having resistance to lighting, insulating property, and dampproof property is preferably used. Epoxy resin, UV-curable resin, acrylic resin, polyisobutylene resin, ethylene vinyl acetate (EVA), ionomer resin, ceramic, and various heat-sealing resin can be used. Various welding methods may also be used. Although an injection port for injecting the solution of the electrolyte composition is necessary, the location of the injection port is not limited as long as it is not on the semiconductor electrode carrying the sensitizing dye and the portions opposing the semiconductor electrode. The method for injecting the solution is not particularly limited; however, a method of injecting the solution to an interior of the above-described cell previously sealed and provided with an injection port for the solution is preferred. In such a case, it is convenient to inject the solution through a capillary phenomenon by providing few drops of the solution to the injection port. If necessary, the injection of the solution may be conducted under vacuum or heating. Upon completion of injection of the solution, the solution remaining at the injection port is removed, and the injection port is sealed. The method for sealing is not particularly limited. If necessary, a glass plate or a plastic substrate may be bonded with sealant to seal the port. In the case where a gel electrolyte containing a polymer or an all-solid electrolyte is used, the polymer solution containing the electrolyte composition and the plasticizer is evaporated by a cast method on the semiconductor substrate onto which the sensitizing dye is adsorbed. After completely removing the plasticizer, sealing is conducted as described above. The sealing is preferably conducted in an inert gas atmosphere or a vacuum using a vacuum sealer or the like. After the sealing, heat and pressure may be applied to sufficiently impregnate the electrolyte into the semiconductor electrode, if necessary.

The dye-sensitized photovoltaic device can be formed to have various shapes according to the usage, and the shape is not particularly limited.

The dye-sensitized photovoltaic device is most typically configured to be a dye-sensitized solar cell. The dye-sensitized photovoltaic device may be a device other than the dye-sensitized solar cell, such as a dye-sensitized optical sensor, for example.

The structure and method according to the first and second inventions can be applied not only to the dye-sensitized photovoltaic device but also to various electronic devices such as integrated circuits having photovoltaic device units.

In this respect, a third invention provides an electronic device including a semiconductor electrode having a sensitizing dye adsorbed thereon, a counter electrode, and an electrolyte layer interposed between the electrodes,

where a molecule having a plurality of acid functional groups for adsorption onto the semiconductor electrode is used as a molecule of the sensitizing dye, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

A fourth invention provides a method for making an electronic device including a semiconductor electrode having a sensitizing dye adsorbed thereon, a counter electrode, and an electrolyte layer interposed between the electrodes,

where a molecule having a plurality of acid functional groups for adsorption onto the semiconductor electrode is used as a molecule of the sensitizing dye, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

The descriptions provided for the first and second inventions also hold true for the third and fourth inventions unless the nature of the inventions otherwise demands.

A fifth invention provides an electronic apparatus including a dye-sensitized photovoltaic device including a semiconductor electrode having a sensitizing dye adsorbed thereon, a counter electrode, and an electrolyte layer interposed between the electrodes,

where a molecule of the sensitizing dye has a plurality of acid functional groups for adsorption onto the semiconductor electrode, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

Basically, the electronic apparatus may be any apparatus and includes those of portable type and non-portable type. Specific examples thereof include cellular phones, mobile apparatuses, robots, persona computers, vehicle-mounted apparatuses, and various house hold electrical appliances. In such a case, the dye-sensitized photovoltaic device is, for example a dye-sensitized solar cell used as the power supply of these electronic apparatuses.

The descriptions provided for the first and second inventions also hold true for the fifth invention unless the nature of the invention otherwise demands.

According to the invention having the above-described features, part of the acid functional groups is neutralized with an alkaline compound to convert the acid functional groups to anions, and the aggregation of the sensitizing dye molecules can be suppressed by repulsion force (charge repulsion) working between the negative charges.

### BRIEF DESCRIPTION OF THE DRAWINGS

FIG. 1 is a cross-sectional view of a relevant part of a dye-sensitized photovoltaic device according to a first embodiment of the present invention.

FIG. 2 is a cross-sectional view of a relevant part of a dye-sensitized photovoltaic device according to a first embodiment of the present invention.

FIG. 3 is a cross-sectional view of a relevant part of a dye-sensitized photovoltaic device according to a second embodiment of the present invention.

FIG. 4 is a cross-sectional view of a relevant part of a dye-sensitized photovoltaic device according to a third embodiment of the present invention.

FIG. 5 includes schematic diagrams for explaining a method for making the dye-sensitized photovoltaic device according to the third embodiment of the present invention.

FIG. 6 is a schematic diagram for explaining problems of existing dye-sensitized photovoltaic devices and means for solving the problem.

### BEST MODE FOR CARRYING OUT THE INVENTION

The embodiments of the present invention will now be described with reference to the drawings. In all drawings of the embodiments, the same or corresponding components are represented by the same reference characters.

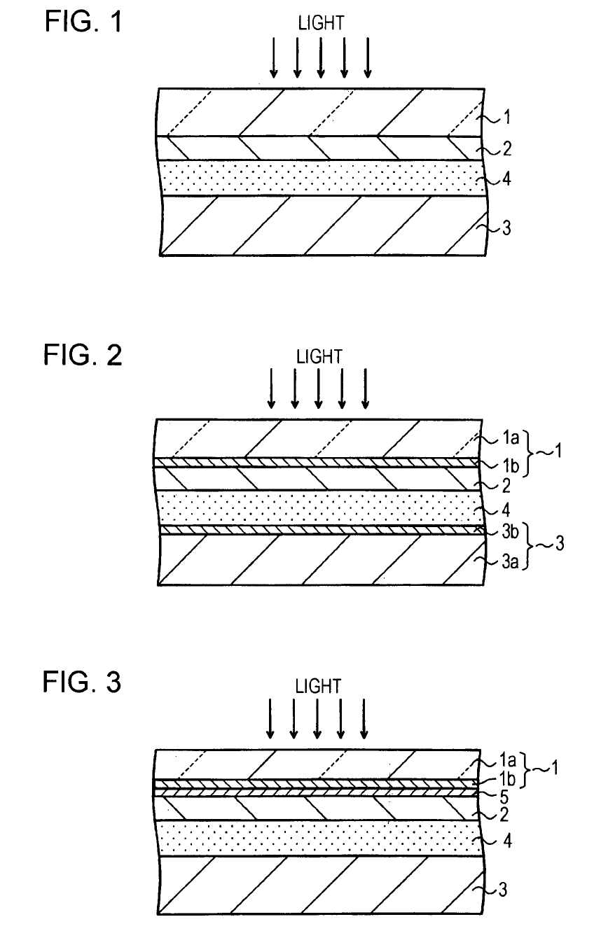

FIG. 1 shows a dye-sensitized photovoltaic device according to a first embodiment of the present invention.

As shown in FIG. 1, in this dye-sensitized photovoltaic device, a transparent conductive substrate 1, which has a dye-carrying semiconductor fine particle layer 2 (dye-sensitized semiconductor electrode) thereon, and a conductive substrate 3, at least surface of which serves as a counter electrode, are arranged to oppose each other with a predetermined gap between the dye-carrying semiconductor fine particle layer 2 and the conductive substrate 3, and an electrolyte layer 4 composed of an electrolyte is enclosed in the gap. The electrolyte layer 4 is sealed with a predetermined sealing member not shown in the drawing.

FIG. 2 shows a dye-sensitized photovoltaic device in which the transparent conductive substrate 1 includes a transparent substrate 1a and a transparent electrode 1b formed on the transparent substrate 1a and the conductive substrate 3 includes a transparent or opaque substrate 3a and a counter electrode 3b formed on the substrate 3a.

The transparent conductive substrate 1 (transparent substrate 1a and transparent electrode 1b), the dye-carrying semiconductor fine particle layer 2, the conductive substrate 3 (substrate 3a and counter electrode 3b), and the electrolyte layer 4 may be appropriately selected from those described above according to need.

The features of the dye-sensitized photovoltaic device are that, in the dye-carrying semiconductor fine particle layer 2, the sensitizing dye molecules are adsorbed on semiconductor fine particles through the acid functional groups of the molecules, and part of the acid functional groups of the sensitizing dye molecules is neutralized into anions with an alkaline compound containing a hydroxide of at least one metal or compound selected from the group consisting of Li, Na, K, tetramethylammonium, tetraethyl ammonium, tetrapropyl ammonium, tetrabutyl ammonium, an imidazolium compound, and a pyridinium compound. In this manner, the repulsive force working between the anions suppresses aggregations of the sensitizing dye molecules and the electron traps between the sensitizing dye molecules can be significantly reduced.

A method for making this dye-sensitized photovoltaic device will now be described.

First, a transparent conductive substrate 1 is prepared. Next, a paste containing dispersed semiconductor fine particles is applied on the transparent conductive substrate 1 to a predetermined gap (thickness). The resulting transparent conductive substrate 1 is heated to a predetermined temperature to sinter the semiconductor fine particles. The transparent conductive substrate 1 with the sintered semiconductor fine particles is immersed in a dye solution or the like so that the semiconductor fine particles carry the dye. In this dye solution, part of the acid functional groups in the sensitizing dye molecules is neutralized in advance into anions with an alkaline compound containing a hydroxide of at least one metal or compound selected from the group consisting of Li, Na, K, tetramethylammonium, tetraethylammonium, tetrapropylammonium, tetrabutylammonium, an imidazolium compound, and a pyridinium compound. Thus, the dye-carrying semiconductor fine particle layer 2 is formed.

The conductive substrate 3 is prepared separately. The transparent conductive substrate 1 and the conductive substrate 3 are arranged to oppose each other with a predetermined gap, e.g., 1 to 100 μm and preferably 1 to 50 μm, between the dye-carrying semiconductor fine particle layer 2 and the conductive substrate 3. A space for enclosing the electrolyte layer 4 is also formed using a predetermined sealing member, and the electrolyte layer 4 is injected from the injection port previously formed for this space. The injection port is subsequently sealed to prepare a dye-sensitized photovoltaic device.

The operation of the dye-sensitized photovoltaic device will now be described.

The light incident from the transparent conductive substrate 1-side and through the transparent conductive substrate 1 excites the dye in the dye-carrying semiconductor fine particle layer 2 to generate electrons. The electrons are rapidly transferred from the dye to the semiconductor fine particles in the dye-carrying semiconductor fine particle layer 2. The dye that lost electrons receive electrons from ions in the electrolyte layer 4, and the molecules that passed on the electrons receive the electrons at the surface of the conductive substrate 3 again. By this series of reactions, electromotive force is generated between the transparent conductive substrate 1 electrically connected to the dye-carrying semiconductor fine particle layer 2, and the conductive substrate 3. Thus, the photoelectric conversion is conducted.

As described above, according to the first embodiment, the acid functional groups are partly converted to anions by neutralization of part of acid functional groups of the sensitizing dye with an alkaline compound, and the aggregation between the sensitizing dye molecules is suppressed by the repulsion force (charge repulsion) working between the negative charges. Thus, the electron traps between the sensitizing dye molecules can be significantly reduced, and the current and voltage of the dye-sensitized photovoltaic device can be notably increased thereby. Consequently, the photoelectric conversion efficiency can be improved.

### EXAMPLES

Examples of the dye-sensitized photovoltaic device will now be described.

### Example 1

TiO₂ fine particles were used as the semiconductor fine particles. A paste containing dispersed TiO₂ fine particles was prepared with reference to Document 4 as follows. To 750 mL of a 0.1 M aqueous nitric acid solution, 125 mL of titanium isopropoxide was gradually added dropwise at room temperature under stirring. Upon completion of dropwise addition, the solution was moved to a thermostat at 80° C., followed by stirring for 8 hours to obtain a white semitransparent sol solution. The solution was left to cool to room temperature, filtered with a glass filter, and diluted to 700 mL. The resulting sol solution was transferred to an autoclave, subjected to hydrothermal treatment at 220° C. for 12 hours, and treated with ultrasonic waves for 1 hour to conduct dispersion. The resulting solution was concentrated with an evaporator at 40° C. so that the TiO₂ content was 20 wt %. To the concentrated sol solution, 20 wt % of polyethylene glycol (molecular weight: 500,000) with respect to TiO₂ in the paste and 30 wt % of anatase TiO₂ with a particle size of 200 nm with respect to TiO₂ in the paste were added, and the resulting mixture was mixed in an degassing mixer to obtain a thickened TiO₂ paste.

The TiO₂ paste thus obtained was applied on a FTO substrate to dimensions of 5 mm×5 mm and a gap of 200 μm by a blade coating method and then retained at 500° C. for 30 minutes to sinter TiO₂ on the FTO substrate. Next, a 0.1 M aqueous TiCl₄ solution was added dropwise to the sintered TiO₂ film and retained for 15 hours at room temperature, followed by washing. Sintering at 500° C. was then again performed for 30 minutes.

The impurities in the TiO₂ sinter thus prepared were removed, and UV exposure was conducted for 30 minutes with a UV lamp to increase the activity.

A thoroughly purified cis-bis(isothiocyanato)-N,N-bis(2,2′-dipyridyl-4,4′-dicarboxylic acid)-ruthenium(II) dihydrate was dissolved in methanol to a concentration of 1 mM. To this solution, NaOH in an amount 0.5 times the number of carboxylic acid groups was added, followed by thorough stirring. After the carboxyl groups were neutralized, the solution was concentrated with an evaporator and recrystallized with diethyl ether. The precipitates were filtered out, washed with diethyl ether, and vacuum-dried at 50° C. for 24 hours.

The resulting cis-bis(isothiocyanato)-N,N-bis(2,2′-dipyridyl-4,4′-dicarboxylic acid)-ruthenium(II) disodium salt was dissolved in a tert-butyl alcohol/acetonitrile mixed solvent (1/1 on a volume basis) to a concentration of 0.3 mM, and the TiO₂ sinter (semiconductor electrode) described above was immersed in this solution at room temperature for 24 hours to allow the sinter to carry the dye. The TiO₂ sinter was washed with an acetonitrile solution of 4-tert-butylpyridine and then acetonitrile and dried in a dark place.

A counter electrode formed by sequentially sputtering Cr to a thickness of 50 nm and Pt to a thickness of 100 nm on a FTO substrate having an injection port of 0.5 mm previously formed therein, spraying an isopropyl alcohol (IPA) solution of chloroplatinic acid to form a coating thereon, and heating the resulting substrate at 385° C. for 15 minutes.

Next, the TiO₂ face of the resulting dye-carrying TiO₂ fine particle layer, i.e., a dye-sensitized semiconductor electrode, and the Pt face of the counter electrode are arranged to oppose each other, and the peripheries thereof were sealed with a 30 μm-thick ionomer resin film and an acrylic UV-curable resin.

An electrolyte composition was separately prepared by dissolving sodium iodide (NaI) 0.030 g, 1-propyl-2,3-dimethylimidazolium iodide 1.0 g, iodine (I₂) 0.10 g, and 4-tert-butylpyridine 0.054 g in methoxyacetonitrile 2 g.

The above-described mixed solution was injected through previously formed injection port of the device by using a liquid-sending pump, and bubbles inside the device were removed by vacuuming. The injection port was sealed with an ionomer resin film, an acrylic resin, and a glass substrate to obtain a dye-sensitized photovoltaic device.

### Examples 2 to 10

Dye-sensitized photovoltaic devices were prepared as in Example 1 except that the dyes and alkaline compounds shown in Table 1 were used.

### Comparative Examples 1 to 4

Dye-sensitized photovoltaic devices were prepared as in Example 1 except that the dyes and alkaline compounds shown in Table 1 were used.

### Comparative Example 5

A dye-sensitized photovoltaic device was prepared as in Example 1 except that the dye shown in Table 1 was used and neutralization with an alkaline compound was not conducted.

| | Alkaline compound | Dye |
|---|---|---|
| Example 1 | NaOH | cis-Bis(isothiocyanato)-N,N- |
| | | bis(2,2′-dipyridyl-4,4′- |
| | | dicarboxylic acid)- |
| | | ruthenium(II) dihydrate |
| Example 2 | LiOH | Same as above |
| Example 3 | KOH | Same as above |
| Example 4 | Tetraethylammonium | Same as above |
| | hydroxide | |
| Example 5 | Tetrapropylammonium | Same as above |
| | hydroxide | |
| Example 6 | Tetramethylammonium | Same as above |
| | hydroxide | |
| Example 7 | 1-Ethyl-3- | Same as above |
| | methylimidazolium | |
| | hydroxide | |
| Example 8 | NaOH | Tris(isothiocyanato)- |
| | | ruthenium(II)-2,2′:6′,2″- |
| | | terpyridine-4,4′,4″-tricarboxylic |
| | | acid |
| Example 9 | KOH | Same as above |
| Example 10 | Tetrabutylammonium | Same as above |
| | hydroxide | |
| Comparative | None (amount of | cis-Bis(isothiocyanato)-N,N- |
| Example 1 | neutralization: 0) | bis(2,2′-dipyridyl-4,4′- |
| | | dicarboxylic acid)-ruthenium(II) |
| | | dihydrate |
| Comparative | NaOH (amount of | Same as above |
| Example 2 | neutralization: 1) | |
| Comparative | Tetraoctylammonium | Same as above |
| Example 3 | hydroxide | |
| Comparative | Tetradecylammonium | Same as above |
| Example 4 | hydroxide | |
| Comparative | None (amount of | Tris(isothiocyanato)- |
| Example 5 | neutralization: 0) | ruthenium(II)-2,2′:6′,2″- |
| | | terpyridine-4,4′,4″-tricarboxylic |
| | | acid |

The dye-sensitized photovoltaic devices of Examples 1 to 10 and Comparative Examples 1 to 5 prepared as above were analyzed to determine the short circuit current, the open circuit voltage, the fill factor, and the photoelectrical conversion efficiency for the I (current)-V (voltage) curve under irradiation with simulating sunlight (AM 1.5, 100 mW/cm²). The results are shown in Table 2.

| | | | | Photoelectric |
|---|---|---|---|---|
| | Short circuit | Open circuit | | conversion |
| | current | current | Fill factor | efficiency |
| | [mA/cm²] | [V] | [%] | [%] |
| Example 1 | 17.5 | 0.781 | 73.9 | 10.1 |
| Example 2 | 18.2 | 0.750 | 72.8 | 9.94 |
| Example 3 | 17.2 | 0.788 | 74.0 | 10.0 |
| Example 4 | 17.2 | 0.776 | 74.0 | 9.88 |
| Example 5 | 17.0 | 0.779 | 74.2 | 9.83 |
| Example 6 | 17.5 | 0.775 | 72.6 | 9.85 |
| Example 7 | 17.3 | 0.777 | 72.3 | 9.71 |
| Example 8 | 18.9 | 0.732 | 72.5 | 10.1 |
| Example 9 | 18.5 | 0.738 | 73.0 | 9.97 |
| Example 10 | 18.4 | 0.730 | 73.2 | 9.83 |
| Comparative | 12.7 | 0.680 | 68.2 | 5.88 |
| Example 1 | | | | |
| Comparative | 4.52 | 0.403 | 53.6 | 0.98 |
| Example 2 | | | | |
| Comparative | 13.5 | 0.701 | 72.3 | 6.84 |
| Example 3 | | | | |
| Comparative | 12.4 | 0.698 | 73.0 | 6.32 |
| Example 4 | | | | |
| Comparative | 6.34 | 0.425 | 52.9 | 1.43 |
| Example 5 | | | | |

Table 2 shows that dye-sensitized photovoltaic devices of Examples 1 to 10 have notably improved fill factor and open circuit voltage compared to those using a dye without partial neutralization or a completely neutralized dye and have excellent photoelectrical conversion efficiency.

A dye-sensitized photovoltaic device according to a second embodiment of the present invention will now be described.

As shown in FIG. 3, in this dye-sensitized photovoltaic device, the transparent conductive substrate 1 has a multilayer structure including the transparent substrate 1a, the transparent electrode 1b, and a metal oxide layer 5, and the dye-carrying semiconductor fine particle layer 2 is formed on the transparent conductive substrate 1. The materials for the transparent substrate 1a, the transparent electrode 1b, and the metal oxide layer 5 can be suitably selected from those previously described according to need. Other features are identical to those of the first embodiment and the description therefor is thus omitted.

The method for making this dye-sensitized photovoltaic device is also substantially the same as that of the first embodiment but differs in that the metal oxide layer 5 is formed over the transparent substrate 1a and the transparent electrode 1b in forming the transparent conductive substrate 1. In particular, for example, FTO substrates used as the transparent substrate 1a and the transparent electrode 1b are thoroughly washed, and an a Nb₂O₅ layer having a thickness of 20 nm is formed thereon as the metal oxide layer 5 by sputtering.

According to the dye-sensitized photovoltaic device of the second embodiment, because the metal oxide layer 5 prevents the transparent electrode 1b from coming into direct contact with the electrolyte used as the electrolyte layer 4, the leakage current by reverse electron transfer reaction can be significantly reduced, the fill factor and the open-circuit voltage can be increased, and the photoelectric conversion efficiency can be further increased while achieving the same advantages as the first embodiment.

A dye-sensitized photovoltaic device according to a third embodiment of the present invention will now be described.

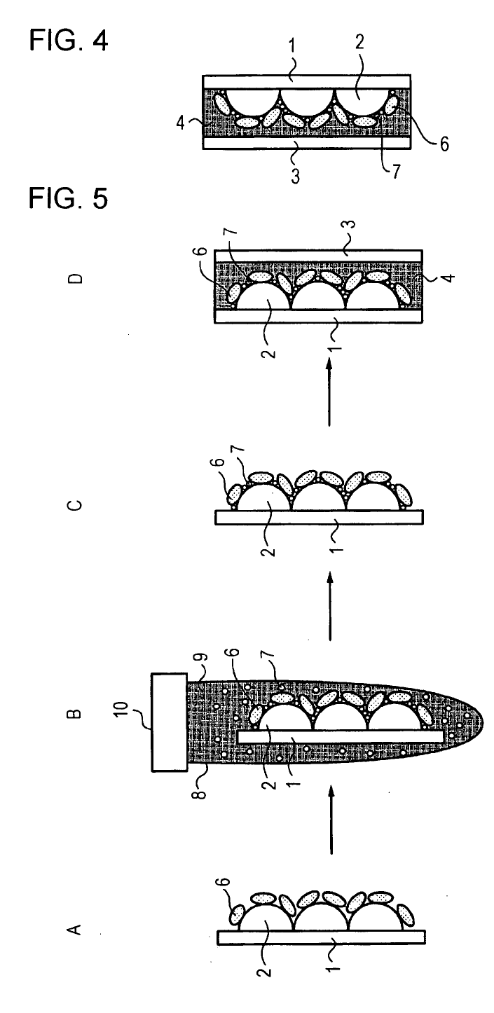

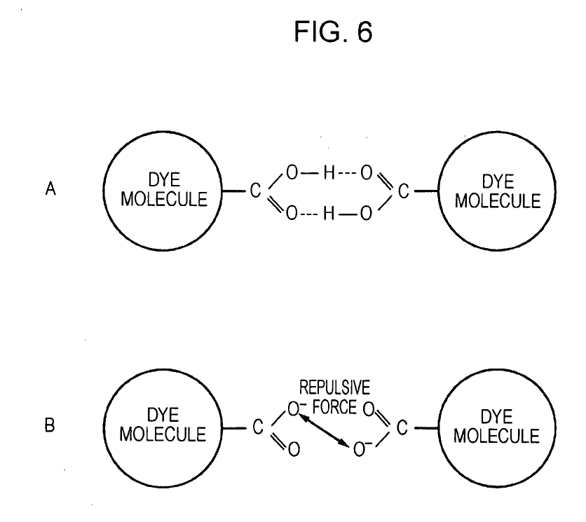

As shown in FIG. 4, in this dye-sensitized photovoltaic device, not only a sensitizing dye 6 is adsorbed on the dye-carrying semiconductor fine particle layer 2, but also an additive 7 is adsorbed on the gaps between the sensitizing dye 6. Unlike related art, no additive is used in the electrolyte that constitutes the electrolyte layer 4. The sensitizing dye 6 and the additive 7 may be appropriately selected from those previously described. Other features are identical with the first embodiment and the description therefor is omitted.

The method for making this dye-sensitized photovoltaic device will now be described.

First, as in the first embodiment, the dye-carrying semiconductor fine particle layer 2 is formed on the transparent conductive substrate 1. FIG. 5A schematically shows the dye-carrying semiconductor fine particle layer 2 in such a state. The dye-carrying semiconductor fine particle layer 2 is formed by the same process as in the first embodiment.

Next, as shown in FIG. 5B, a solution 9 of the additive 7 dissolved in a solvent is placed in a container 8, and the transparent conductive substrate 1 with the dye-carrying semiconductor fine particle layer 2 formed thereon is immersed in the solution 9. The container 8 is covered with a lid 10 and the additive 7 is allowed to adsorb onto the dye-carrying semiconductor fine particle layer 2. In particular, as the solution 9, an electrolyte containing NaI 0.1 M, 1-propyl-2,3-dimethylimidazolium iodide (DMP II) 0.6 M, I₂ 0.05 M, and a methoxyacetonitrile (MeACN) solution of an additive, i.e., tert-butylpyridine (TBP), 0.5 M is prepared. The dye-carrying semiconductor fine particle layer 2 is immersed in this electrolyte for 5 to 10 minutes to allow the additive 7, i.e., tert-butylpyridine, to adsorb on the surface of the dye-carrying semiconductor fine particle layer 2 at the sites on which the sensitizing dye could not adsorb. The electrolyte remaining on the dye-carrying semiconductor fine particle layer 2 is rinsed away with methoxyacetonitrile, followed by air drying.

After adsorption of the additive 7, the transparent conductive substrate 1 with the dye-carrying semiconductor fine particle layer 2 is taken out from the container 8. The surface of the dye-carrying semiconductor fine particle layer 2 is then washed. FIG. 5C shows the dye-carrying semiconductor fine particle layer 2 in such a state.

The conductive substrate 3 is prepared separately. As shown in FIG. 5D, the transparent conductive substrate 1 and the conductive substrate 3 are arranged so that the dye-carrying semiconductor fine particle layer 2 and the conductive substrate 3 oppose each other with a predetermined gap therebetween while creating a space for enclosing the electrolyte layer 4 by using a predetermined sealing material. The electrolyte layer 4 is injected from the injection port formed in the space in advance. The injection port is then sealed to form the dye-sensitized photovoltaic device.

According to the dye-sensitized photovoltaic device of the third embodiment, because the additive 7 is adsorbed on the dye-carrying semiconductor fine particle layer 2 in advance and an electrolyte free of the additive 7 is used as the electrolyte layer 4, reverse electron transfer reaction can be prevented by the additive 7 preliminarily adsorbed on the dye-carrying semiconductor fine particle layer 2, degradation of photoelectric conversion efficiency over time can be prevented, and the lifetime can be prolonged while achieving the same advantages as the first embodiment.

Although the embodiments and examples of the present invention are specifically described above, the invention is not limited to the embodiments and examples and includes various modifications and alterations within the spirit of the present invention.

For example, the numerical values, structures, shapes, materials, ingredients, processes described in the embodiments and the examples are merely examples and different numerical values, structures, shapes, materials, ingredients, and processes may be used as necessary.

For example, the second embodiment may be combined with the third embodiment.

According to the present invention, aggregation among the sensitizing dye molecules adsorbed on the semiconductor electrode is suppressed, and the electron traps between the sensitizing dye molecules can be reduced. In this manner, the current and the voltage of the dye-sensitized photovoltaic device can be markedly increased, and the photoelectrical conversion efficiency can be enhanced.

1. A dye-sensitized photovoltaic device including a semiconductor electrode having a sensitizing dye adsorbed thereon, a counter electrode, and an electrolyte layer interposed between the electrodes,
wherein a molecule of the sensitizing dye has a plurality of acid functional groups for adsorption onto the semiconductor electrode, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

2. The dye-sensitized photovoltaic device according to claim 1, wherein the amount of neutralization of the acid functional groups is 0.25 to 0.75 with respect to the number of acid functional groups in the sensitizing dye molecule.

3. The dye-sensitized photovoltaic device according to claim 1, wherein the acid functional groups are carboxyl groups.

4. The dye-sensitized photovoltaic device according to claim 1, wherein the molecule of the sensitizing dye is a complex of at least one metal selected from the group consisting of Ru, Os, Ir, Pt, Co, Fe, and Cu, the molecule containing a pyridine ring or an imidazolium ring as a ligand.

5. The dye-sensitized photovoltaic device according to claim 1, wherein the basic skeleton of the molecule of the sensitizing dye is cis-bis(isothiocyanato)-N,N-bis(2,2′-dipyridyl-4,4′-dicarboxylic acid)-ruthenium(II) or tris(isothiocyanato)-ruthenium(II)-2,2′:6′,2″-terpyridine-4,4′,4″-tricarboxylic acid.

6. The dye-sensitized photovoltaic device according to claim 1, wherein the semiconductor electrode comprises semiconductor fine particles.

7. The dye-sensitized photovoltaic device according to claim 1, wherein the dye-sensitized photovoltaic device is a dye-sensitized solar cell.

8. A method for making a dye-sensitized photovoltaic device including a semiconductor electrode having a sensitizing dye adsorbed thereon, a counter electrode, and an electrolyte layer interposed between the electrodes,
wherein a molecule having a plurality of acid functional groups for adsorption onto the semiconductor electrode is used as a molecule of the sensitizing dye, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

9. An electronic device including a semiconductor electrode having a sensitizing dye adsorbed thereon, a counter electrode, and an electrolyte layer interposed between the electrodes,
wherein a molecule of the sensitizing dye has a plurality of acid functional groups for adsorption onto the semiconductor electrode, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

10. A method for making an electronic device including a semiconductor electrode having a sensitizing dye adsorbed thereon, a counter electrode, and an electrolyte layer interposed between the electrodes,
wherein a molecule having a plurality of acid functional groups for adsorption onto the semiconductor electrode is used as a molecule of the sensitizing dye, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.

11. An electronic apparatus including a dye-sensitized photovoltaic device including a semiconductor electrode having a sensitizing dye adsorbed thereon, a counter electrode, and an electrolyte layer interposed between the electrodes,
wherein a molecule of the sensitizing dye has a plurality of acid functional groups for adsorption onto the semiconductor electrode, and part of the acid functional groups is neutralized with an alkaline compound which is a hydroxide of at least one metal or compound selected from the group consisting of Li, Na, K, tetramethylammonium, tetraethylammonium, tetrapropylammonium, tetrabutylammonium, an imidazolium compound, and a pyridinium compound.
